(19) United States
(12) Patent Application Publication
(10) Pub. No.: US 2004/0199838 A1
(43) Pub. Date: Oct. 7, 2004

(54) Enhanced boundary-scan method and apparatus providing tester channel reduction

(76) Inventors: Paul William Rutkowski, Bridgewater, NJ (US); Larry Christopher Wall, Fogelsville, PA (US)

Correspondence Address: Ryan, Mason & Lewis, LLP, 90 Forest Avenue, Locust Valley, NY, 11560, US

(21) Appl. No.: 10/392,011

(22) Filed: Mar. 19, 2003

(51) Int. Cl. H03K 19/00; G01R 31/28

(52) U.S. Cl. 714/724

(57) ABSTRACT

An integrated circuit or other electronic circuitry is tested by arranging device pins into multiple-pin groups, and permitting the device pins of the group to share a single tester channel of a piece of test equipment. More particularly, a group comprising a plurality of device pins of the electronic circuitry is designated, and assigned to one of a plurality of tester channels in the test equipment. A test may then be performed on the electronic circuitry, via the assigned tester channel, utilizing at least a subset of the device pins in the designated multiple-pin group. Advantageously, the invention allows high pin count integrated circuits to be tested using inexpensive test equipment platforms.

### FIELD OF THE INVENTION

The present invention relates generally to integrated circuits and other types of electronic circuitry, and more particularly to techniques for testing such circuitry.

### BACKGROUND OF THE INVENTION

A well-known standard for use in testing integrated circuits and other types of electronic circuitry has been developed by the Joint Test Action Group (JTAG) and is defined in Institute of Electrical and Electronics Engineers (IEEE) Standard 1149.1, “IEEE Standard Test Access Port and Boundary-Scan Architecture,” IEEE, New York, N.Y., October, 1993, which is incorporated by reference herein. For example, in the context of an integrated circuit, the IEEE 1149.1 standard defines test logic that can be included in a given integrated circuit to provide standardized approaches to testing the interconnections between integrated circuits once they have been assembled onto a printed circuit board or other substrate, testing the integrated circuit itself, and observing or modifying circuit activity during normal circuit operation.

The test logic includes a boundary-scan register as well as other elements and is accessible through a Test Access Port (TAP) associated with the integrated circuit. The test logic allows test instructions and associated test data to be fed into the integrated circuit, and allows the results of execution of the instructions to be subsequently read out. All information, i.e., test instructions, test data and test results, are communicated in a serial format. The integrated circuit test process is also commonly referred to as “debugging.”

A significant problem associated with conventional techniques involving the above-noted IEEE 1149.1 standard is that provision of“full-contact” testing of high pin count integrated circuits can require prohibitively expensive test machines. Such full-contact testing refers generally to testing arrangements in which each pin of a given integrated circuit can be individually controlled through a corresponding separate tester channel. Previous attempts to provide full-contact testing for high pin count integrated circuits have generally been directed to constructing test machines having a larger channel capacity, always with a single tester channel of a given machine being utilized to test of each of the device pins. As indicated above, this type of approach unduly increases the cost of the test machines.

Another approach avoids the need for conventional test machines through the use of improved design for test (DFT) architectures. Such DFT architectures typically utilize boundary-scan techniques for functional verification and may include thousands of DC-only pins for buffer verification. However, the implementation of such DFT architectures generally also involves substantial capital expenditures.

It is therefore apparent that a need exists for improved integrated circuit boundary-scan testing techniques which can provide full-contact testing of high pin count integrated circuits without the excessive costs associated with the above-noted conventional techniques.

### SUMMARY OF THE INVENTION

The present invention provides enhanced boundary-scan techniques which in an illustrative embodiment can provide full-contact testing of an integrated circuit or other electronic circuitry without requiring a separate tester channel for each device pin.

In accordance with one aspect of the invention, an integrated circuit or other electronic circuitry is tested by arranging device pins into multiple-pin groups, and permitting the device pins of the group to share a single tester channel of a piece of test equipment. More particularly, a group comprising a plurality of device pins of the electronic circuitry is designated, and assigned to one of a plurality of tester channels in the test equipment. A test is then performed on the electronic circuitry, via the assigned tester channel, utilizing at least a subset of the device pins in the designated multiple-pin group.

In an illustrative embodiment of the invention, boundary-scan logic circuitry included in the electronic circuitry to be tested includes a boundary-scan register and a boundary-scan accessible pullup/pulldown control register.

The boundary-scan register comprises a plurality of sets of boundary-scan cells. Each of the sets of boundary-scan cells includes one or more boundary-scan cells and is associated with a corresponding one of the device pins. For example, each of the sets of boundary-scan cells may include at least a boundary-scan control cell, a boundary-scan output cell, and a boundary-scan input cell.

The pullup/pulldown control register comprises a plurality of sets of pullup/pulldown cells, wherein each of the sets of pullup/pulldown cells includes one or more pullup/pulldown cells and is associated with a corresponding one of the device pins.

The boundary-scan logic circuitry is coupled to bidirectional buffers, with each of the bidirectional buffers being associated with a corresponding one of the device pins.

Advantageously, the techniques of the invention allow otherwise conventional test machines and other test equipment to test high pin count integrated circuits, using a number of tester channels which is much less than the number of device pins to be tested.

### BRIEF DESCRIPTION OF THE DRAWINGS

FIG. 1 shows a system for testing an integrated circuit in accordance with an illustrative embodiment of the invention.

FIG. 2 is another view of the FIG. 1 system illustrating the manner in which multiple device pins share a common tester channel in accordance with the techniques of the invention.

FIG. 3 illustrates the interconnection of multiple pull-up or pull-down cells in the integrated circuit of the FIG. 1 system.

FIGS. 4 and 5 show other illustrative embodiments of a system for testing an integrated circuit in accordance with the invention.

FIGS. 6A and 6B show more detailed schematic diagrams of respective system-mode input and output configurations of portions of the integrated circuit of FIG. 5.

FIGS. 7A through 7D are schematic diagrams of illustrative boundary-scan logic circuitry.

FIG. 8 shows another illustrative embodiment of a system for testing an integrated circuit in accordance with the invention, more particularly illustrating a technique for addressing ganging contention scenarios.

FIGS. 9A through 9F illustrate example tests that may be performed in a test system in accordance with the invention.

### DETAILED DESCRIPTION OF THE INVENTION

The present invention will be illustrated herein in the context of test systems comprising exemplary integrated circuits to be tested, and associated automated test equipment (ATE) for performing the testing. It should be understood, however, that the particular arrangements shown are provided by way of illustrative example only, and not intended to limit the scope of the invention in any way. As will become apparent, the techniques of the invention are utilizable in a wide variety of test applications involving integrated circuits or other electronic circuitry. The term “electronic circuitry” is intended to include a single integrated circuit, a set of two or more integrated circuits, or other types and arrangements of one or more electronic devices.

The present invention in accordance with one aspect thereof incorporates enhanced boundary-scan circuitry into an integrated circuit or other device to be tested so as to permit the associating or “ganging” together of multiple device pins with a single tester channel.

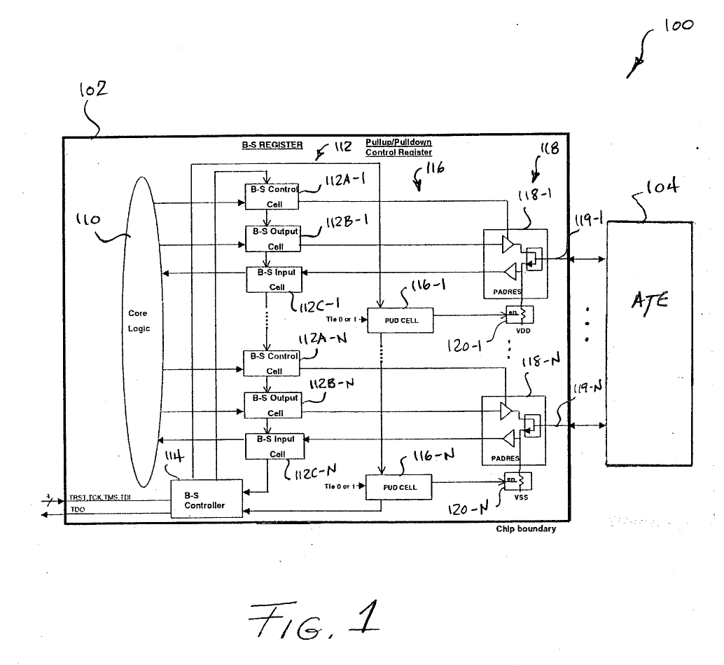

FIG. 1 shows a test system 100 configured in accordance with an illustrative embodiment of the invention. The system 100 includes a device under test 102 and ATE 104. It will be assumed for simplicity of description that the device under test 102 comprises an integrated circuit or “chip,” but the techniques of the invention can be used to test other types of electronic circuitry.

The ATE 104 may be of a type well-known to those skilled in the art, suitable for testing electronic circuitry utilizing boundary-scan techniques such as those defined by the above-noted IEEE 1149.1 standard. Typically, the ATE 104 is implemented using a computer, a workstation, or other information processing device comprising a processor and memory. In other embodiments, the ATE 104 may be replaced with non-automated test machinery. The invention does not require any particular type of test equipment. In general, the term “test equipment” as used herein is intended to include ATE, non-automated test machinery, or other types of test devices, as well as combinations thereof. Such test equipment typically includes a plurality of tester channels, where the term “tester channel” refers to a signal pathway or other connection for directing signals to and/or receiving signals from a given device under test.

The integrated circuit 102 in this illustrative embodiment includes core logic 110, a boundary-scan (B-S) register 112, a boundary-scan controller 114, a pullup/pulldown control register 116, and a set of bidirectional buffers 118, arranged as shown. The core logic 110 may also be referred to as core system logic or system logic herein.

The term “pullup/pulldown” as used herein is intended to include pullup only, pulldown only, or both pullup and pulldown.

The boundary-scan register 112 includes N sets of three boundary-scan cells each, namely, a control boundary-scan cell 112A-i, an output boundary-scan cell 112B-i, and an input boundary-scan cell 112C-i, where the index i=1, 2, . . . N denotes a particular one of the N sets of cells in the integrated circuit 102. Each of the cells is coupled to the core logic 110 and to the boundary-scan controller 114.

Although the boundary-scan register 112 as shown in FIG. 1 includes sets of three boundary scan cells, that is, control, output and input cells, this is by way of example only. Other embodiments may utilize, for example, sets of two cells, with each set including a control boundary-scan cell as well as a bidirectional boundary-scan cell that can change direction to serve both the output and input directions. An example of a bidirectional cell of this type is sometimes referred to in the art as a “BC_{—}7-type” cell. Other types and arrangements of cells can also be used to implement the invention.

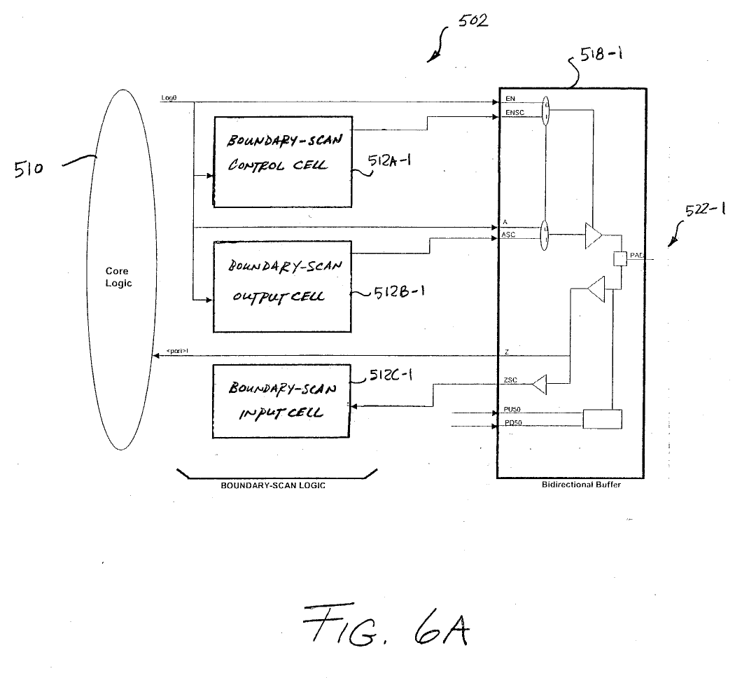

The pullup/pulldown control register 116 includes N sets of pullup/pulldown (PUD) cells, each set in this example including a single pullup/pulldown cell 116-i, where again i denotes an index that may take on values between 1 and N. Although each of the N sets of pullup/pulldown cells in this example includes only a single cell, this is by way of example only. Other embodiments of the invention may include more pullup/pulldown cells in each set of cells, and different sets may include different numbers of cells. An embodiment with two pullup/pulldown cells in each set of cells will be described below in conjunction with FIG. 5.

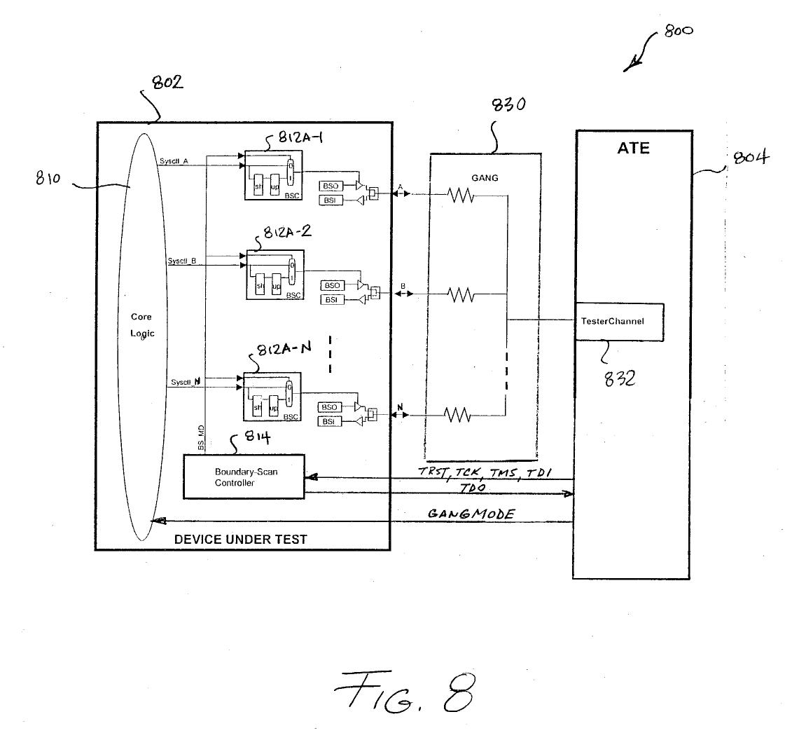

With continued reference to FIG. 1, the boundary-scan controller 114 receives off-chip inputs TRST, TCK, TMS and TDI, and generates an output TDO. These signals are defined in accordance with the above-cited IEEE 1149.1 standard. The corresponding signal lines are typically coupled to the ATE 104, as is well known, although for simplicity of illustration these connections are not explicitly shown in FIG. 1. The coupling of these signal lines with the ATE is illustrated, for example, in the system shown in FIG. 8.

The boundary-scan controller 114 supplies inputs to and receives outputs from each of the boundary-scan cells of the boundary-scan register 112. Similarly, the boundary-scan controller 114 supplies inputs to and receives outputs from each of the pullup/pulldown cells 116-i of the pullup/pulldown control register 116.

In this embodiment, the boundary-scan cells of the boundary-scan register 112 may be controlled using conventional commands defined by the IEEE 1149.1 standard, such as EXTEST and SAMPLE/PRELOAD commands. However, pullup/pulldown control is not defined by the IEEE 1149.1 standard. As a result, the pullup/pulldown cells of the pullup/pulldown control register 116 are controlled using a “private” or non-standard boundary-scan command, that is, one not defined by the IEEE 1149.1 standard. This non-standard boundary-scan command, also referred to herein as a pullup/pulldown control command, allows the pullup/pulldown cells to be programmed through the 5-pin boundary-scan controller interface comprising the above-noted signal lines TRST, TCK, TMS, TDI, TDO.

A given one of the bidirectional buffers 118, that is, a bidirectional buffer 118-i, is coupled as shown to a corresponding one of the sets of N boundary-scan cells of the boundary-scan register 112. More specifically, an output buffer portion of the bidirectional buffer 118-i is coupled between an output of the boundary-scan output cell 112B-i and a device pin 119-i of the integrated circuit 102. Similarly, an input buffer portion of the bidirectional buffer 118-i is coupled between the device pin 119-i and an input of the boundary-scan input cell 112C-i. An output of the boundary-scan control cell 112A-i is applied to a control input of the output buffer portion of the bidirectional buffer 118-i, and controls the state of that output buffer portions, e.g., its placement in a normal output mode or a tristated mode.

In the illustrative embodiments, a separate bidirectional buffer is associated with each of the device pins that are to be grouped to share a common tester channel. This provides controllability of the pin, since the output boundary-scan cell can launch logic values to the pin. It also provides observability of the pin. More specifically, because the buffer may be configured to provide self-monitoring or “loopback” operation, the value on the pin can always be monitored by the boundary-scan cell connected to the input side of the buffer.

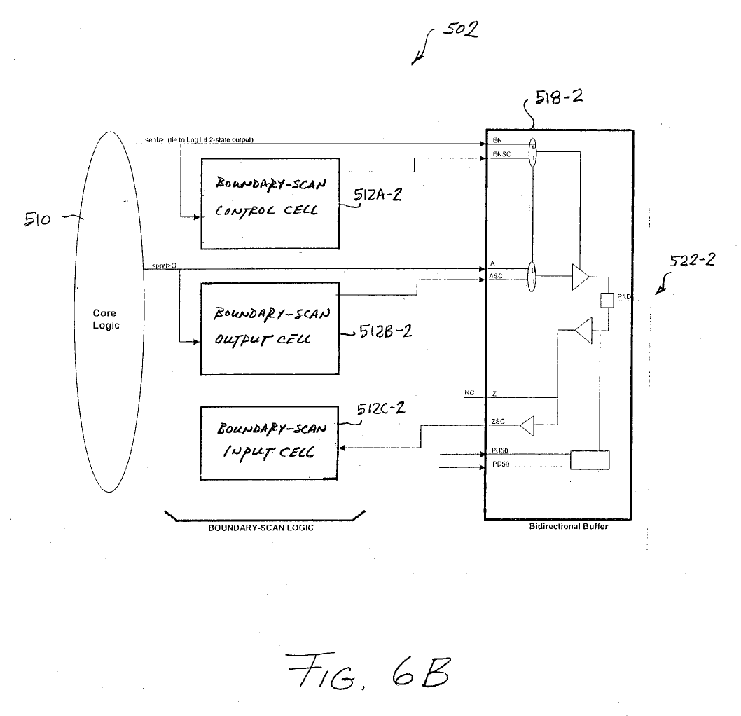

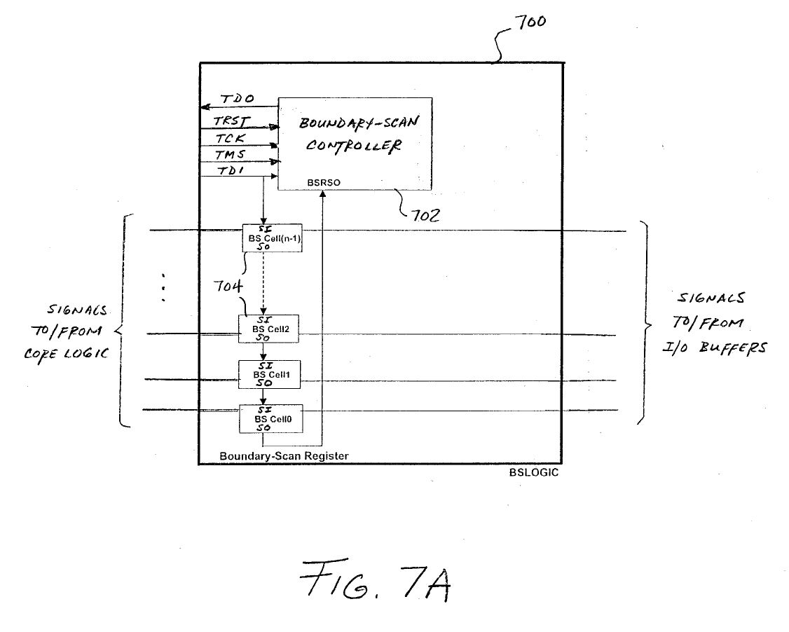

Although only bidirectional buffers may be ganged in the illustrative embodiment, this does not restrict the system-mode behavior of the pins. For example, even if a given device pin serves solely as an input during system mode, a bidirectional buffer can be used and the given pin can operate as a bidirectional pin during boundary-scan testing. FIGS. 6A and 6B to be described below show examples of device pins whose system function is input only and output only, respectively, but which operate as bidirectional pins in boundary-scan mode.

Also associated with the bidirectional buffer 118-i is a controllable pad resistor 120-i which is enabled or disabled based on the output of a corresponding pullup/pulldown cell 116-i. An input to the pullup/pulldown cell 116-i may be tied to a logic “0” or a logic “1” level as indicated in the figure, in accordance with the particular enable operation required. Certain of the controllable pad resistors may provide pullup of the associated device pin to an upper supply voltage line VDD, while others may provide pulldown of the associated device pin to a lower supply voltage VSS. The controllable pad resistor 120-1 is an example of the former, while the controllable pad resistor 120-N is an example of the latter. Of course, numerous alternative pullup and pulldown arrangements are possible, as will be appreciated by those skilled in the art and will be more readily apparent from alternative embodiments to be described below.

It should also be noted that the pullup/pulldown mechanism need not be implemented using a resistor. For example, other embodiments may utilize one or more field effect transistors (FETs) or other circuitry to provide the pullup/pulldown mechanism.

It is generally preferable that the bidirectional buffers associated with a given grouping of multiple pins sharing a common tester channel of the ATE have substantially the same DC characteristics. For example, the device pins corresponding to a set of TTL buffers may be designated as a group to share a single tester channel. This facilitates performance of certain tests, such as leakage testing.

The device pins 119-1 through 119-N of the integrated circuit 102 are coupled to ATE 104 as shown. It should be noted that the term “device pin” as used herein is intended to be construed broadly so as to encompass, by way of example, a lead associated with a leadframe of a packaged integrated circuit, a bond pad, or other signal line or portion thereof associated with input or output access to the integrated circuit at the chip boundary.

Advantageously, the enhanced boundary-scan circuitry comprising the boundary-scan register 112, boundary-scan controller 114, pullup/pulldown control register 116, bidirectional buffers 118 and controllable pad resistors 120 allows the device pins 119 of the integrated circuit 102 to be grouped together and associated with a common single tester channel of the ATE 104. More specifically, as will be described in greater detail below, a group comprising a plurality of the device pins 119 may be designated, and the designated multiple-pin group assigned to one of a plurality of tester channels of the ATE 104. A test may then be performed on the integrated circuit 102, via the assigned tester channel, utilizing at least a subset of the device pins in the designated multiple-pin group. The process of grouping multiple device pins to share a single tester channel of the ATE 104 is also referred to herein as “ganging” of device pins.

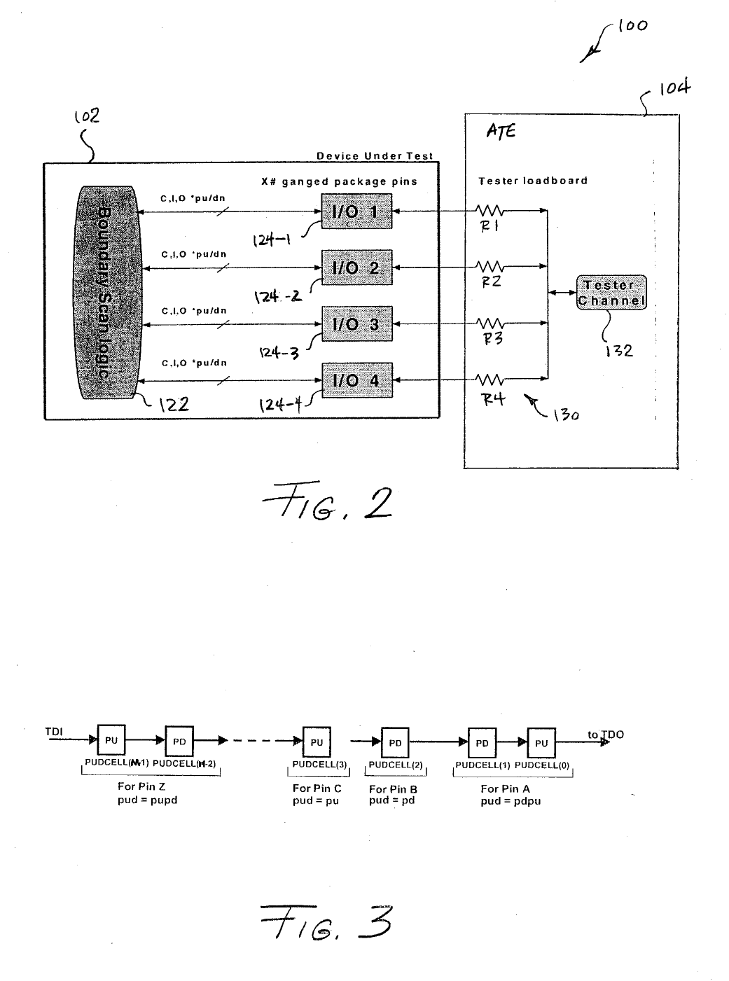

FIG. 2 illustrates an example of the above-described grouping process as implemented in the test system 100 of FIG. 1. The integrated circuit 102 in this example comprises boundary-scan logic 122 which may include the elements 112, 114 and 116 previously described in conjunction with FIG. 1. Input/output circuitry 124-1, 124-2, 124-3 and 124-4 is associated with respective device pins 119-1, 119-2, 119-3 and 119-4, and may be viewed as including in addition to the device pins the particular circuitry associated with the elements 118 and 120 previously described in conjunction with FIG. 1.

The ATE 104 includes a tester load board 130 four signal paths coupled to a common tester channel 132. In this example, the four device pins 119-1, 119-2, 119-3 and 119-4 of the integrated circuit 102 are grouped together and assigned to the single tester channel 132. More specifically, each of the device pins 119-1, 119-2, 119-3 and 119-4, associated with the respective input/output circuit 124-1, 124-2, 124-3 and 124-4, is coupled via a corresponding one of four resistors R1, R2, R3 and R4 of the tester load board 130 to the tester channel 132. The device pins 119, as previously indicated, may comprise package pins of the integrated circuit 102. Signals passed between the input/output circuitry 124 and the boundary-scan logic 122 may include boundary-scan control (C) signals, boundary-scan input (I) signals, boundary-scan output (O) signals, and pullup/pulldown signals, as indicated in the figure.

The resistors R1, R2, R3 and R4 of the tester load board 130 provide isolation between the device pins of a given group of ganged device pins sharing the tester channel 132, and also facilitate determination of output levels as well as short detection, e.g., checking for bridged nets.

Suitable values for the resistors R1, R2, R3 and R4 are 100 ohms, although other values can be used. The particular values used will generally depend on the type of circuitry being tested, the configuration of the ATE, and other application-specific factors. Appropriate values for given application can be readily determined in a straightforward manner. It is to be appreciated that the particular load board circuitry shown in FIG. 2, and its placement and configuration relative to the ATE, is exemplary only. Those skilled in the art will recognize that the invention can be implemented using numerous other test arrangements.

Although only a single group of four device pins is shown as sharing the tester channel 132 in the FIG. 2 embodiment, this is by way of example only. Any number of device pins may be grouped together and associated with a single tester channel using the techniques of the invention. It should be noted, however, that the maximum number of pins may be limited by factors such as the impact of buffer leakage currents on measurement accuracy.

Moreover, a given ATE will generally include multiple tester channels, and each may be associated with a different group of multiple device pins of the integrated circuit 102. The particular arrangement shown in the FIG. 2 embodiment is therefore considerably simplified for clarity of illustration.

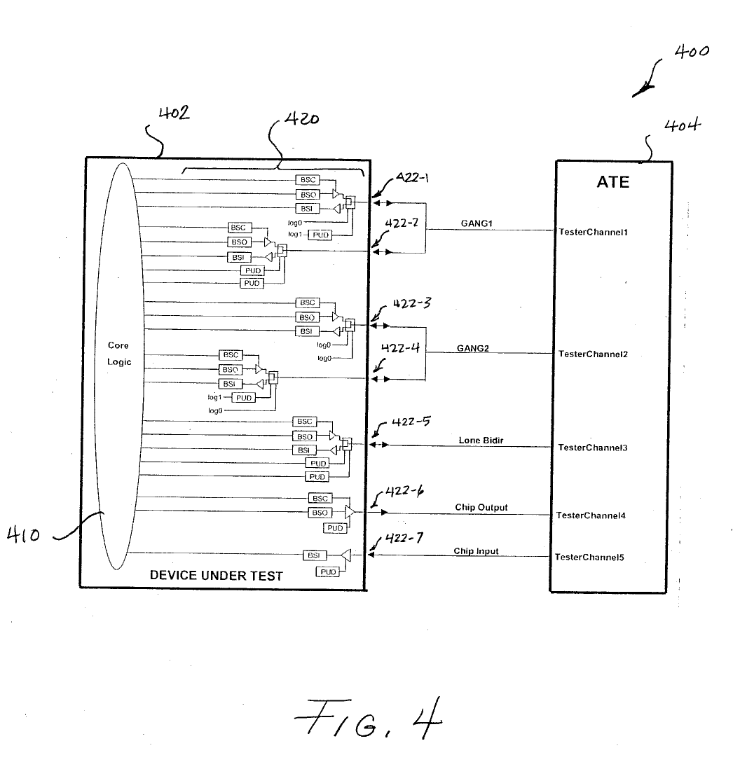

FIG. 3 illustrates the interconnection of multiple pullup/pulldown cells of the pullup/pulldown control register 116. As noted above, a given device pin may have one or more pullup/pulldown cells associated therewith. In the FIG. 3 example, it is assumed that the integrated circuit under test includes device pins A through Z, with a total of M pullup/pulldown cells being distributed over these device pins. Device pin A has both a pullup cell (PU) and a pulldown cell (PD) associated therewith. The pullup/pulldown functionality associated with pin A is pulldown followed by pullup (pud=pdpu). Device pins B and C each have only a single pullup/pulldown cell associated therewith. More specifically, pin B includes only pulldown functionality (pud=pd), while pin C include only pullup functionality (pud=pu). Device pin Z, like device pin A, includes both a pullup cell and a pulldown cell, but arranged in the opposite order, such that its pullup/pulldown functionality is pullup followed by pulldown (pud=pupd).

The M pullup/pulldown cells in the FIG. 3 example may be viewed as being interconnected in series between the TDI input to the boundary-scan controller 114 and the TDO output of the boundary-scan controller. Numerous alternative arrangements are possible.

In the test system 100 illustrated in conjunction with FIGS. 1-3, the enhanced boundary-scan circuitry provides individual control of each device pin within a given designated multiple-pin group sharing a single tester channel of the ATE. This arrangement thus permits individual DC verification of each device pin, including performance of tests to verify input levels (VIL, VIH), output levels (VOL, VOH), tristate leakage, pullup and pulldown behavior, the presence of opens, shorts or other anomalies, etc. These and other tests can be performed for each device pin in a given group of device pins using only the 5-pin boundary-scan controller interface (TRST, TCK, TMS, TDI, TDO) and the corresponding single tester channel, regardless of the particular number of device pins in the group.

In one application of the above-described grouping of pins for association with a common tester channel, there may be only a single ganging configuration per device. For example, after manufacture the devices may each go through a package test only once and each will use the same load board setup, such that only a single static grouping of device pins is required. However, once a given device is fabricated to include the enhanced boundary-scan circuitry of the invention, multiple distinct ganging configurations are possible. For example, different sets of device pins may be ganged to fit particular ATE needs. In this sense, the device pin groupings can be considered scalable. Other types of dynamic grouping of device pins can also be used.

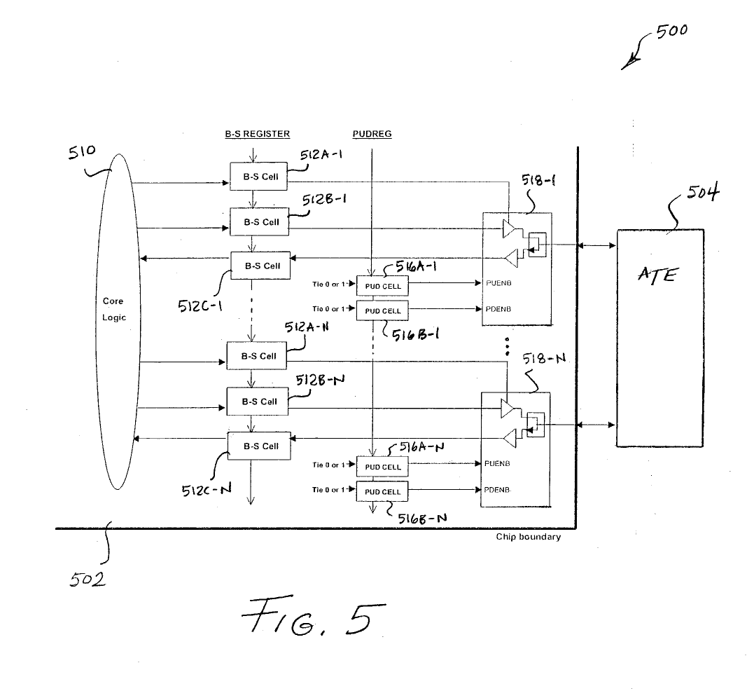

Alternative embodiments of the invention will now be described with reference to FIGS. 4 through 8.

FIG. 4 shows a test system 400 configured in accordance with another illustrative embodiment of the invention. The system 400 includes a device under test 402 and ATE 404. The device under test 402, which may comprise an integrated circuit or other electronic circuitry, includes core logic 110 and boundary-scan and buffer circuitry 420. The device under test 402 will also typically include a boundary-scan controller, although this element is omitted from the figure for simplicity and clarity of description.

In this example, the device under test 402 as shown includes seven device pins, denoted 422-1 through 422-7. The ATE 404 includes five tester channels, denoted Tester Channel 1 through Tester Channel 5. Device pins 422-1 and 422-2 have been designated as a group GANG 1 and assigned to share Tester Channel 1. Similarly, device pins 422-3 and 422-4 have been designated as a group GANG 2 and assigned to share Tester Channel 2. Device pins 422-5, 422-6 and 422-6 are not ganged, and each is associated with a respective one of Tester Channel 3, Tester Channel 4 and Tester Channel 5.

Within the boundary-scan and buffer circuitry 420, elements BSC, BSO and BSI denote boundary-scan control cells, boundary-scan output cells and boundary-scan input cells, respectively. Elements PUD denote pullup/pulldown cells. These cells and other elements of the boundary-scan and buffer circuitry operate in substantially the same manner as that described previously in the context of the embodiment of FIGS. 1-3.

Although not shown in FIG. 4, a tester load board or other similar device may be incorporated within ATE 404, or arranged externally to the ATE in a manner similar to that shown in FIG. 2. The tester load board is omitted from FIG. 4 for simplicity and clarity of illustration. However, such a tester load board will generally include a series resistor for each device pin sharing a common tester channel, as described previously herein.

FIG. 5 shows a test system 500 configured in accordance with another illustrative embodiment of the invention. The system 500 includes a device under test in the form of an integrated circuit 502, and ATE 504. Like the FIG. 1 system, the system 500 includes N device pins coupled to the ATE. Also, the integrated circuit 502 will typically include a boundary-scan controller, although this element is again omitted from the figure for simplicity and clarity of description.

Associated with each device pin is a set of boundary-scan cells of a boundary-scan register, including a boundary-scan control cell 512A-i, a boundary-scan output cell 512B-i, and a boundary-scan input cell 512C-i, and a set of pullup/pulldown cells of a pullup/pulldown control register, including pullup/pulldown cells 516A-i and 516B-i, where again i denotes an index which may take on values from 1 to N.

Also associated with each device pin is a bidirectional buffer 518-i, which includes a pullup enable input coupled to an output of the pullup/pulldown cell 516A-i and a pulldown enable input coupled to an output of the pullup/pulldown cell 516B-i.

Again, although not shown in FIG. 5, a tester load board or other similar device may be incorporated within ATE 504, or arranged externally to the ATE in a manner similar to that shown in FIG. 2, and will generally include a series resistor for each device pin sharing a common tester channel.

The FIGS. 4 and 5 systems generally operate in a manner similar to that of the FIG. 1 system previously described.

FIGS. 6A and 6B show more detailed schematic diagrams of respective system-mode input and output configurations of a given portion of the integrated circuit of FIG. 5. These diagrams illustrate in greater detail the boundary-scan logic comprising boundary-scan cells 512A-i, 512B-i and 512C-i, and the corresponding bidirectional buffer 518-i, all associated with a given device pin, namely a device pin 522-i. For FIGS. 6A, it is assumed that i=1, while for FIG. 6B it is assumed that i=2. FIGS. 6A and 6B thus illustrate boundary-scan logic circuitry and bidirectional buffer circuitry associated with different device pins. The pullup/pulldown cells 516, which are generally utilized only in test mode, are omitted from these figures for clarity. Also, as in FIG. 5, the boundary-scan controller is not explicitly shown in FIGS. 6A and 6B.

As noted previously, FIGS. 6A and 6B show examples of device pins 522-1 and 522-2 whose system function is input only and output only, respectively, but which operate as bidirectional pins in boundary-scan mode. Associated with each of these device pins 522-1 and 522-2 is a bond pad as shown.

With reference initially to FIG. 6A, this figure illustrates the manner in which the boundary-scan logic and bidirectional buffer circuitry may be configured for operation in a system mode as an ordinary input buffer for device pin 522-1. The system mode function of device pin 522-1 is therefore input only. Note that the core logic 510 only connects to the incoming signal from the buffer 518-1 via the signal line denoted <port>I. However, there are still three boundary-scan cells, namely, control cell 512A-1, output data cell 512A-2 and input data cell 512C-1. During boundary scan mode, these three cells allow full bidirectional testing of the pin 522-1.

In the FIG. 6A example, inputs of the cells 512A-1 and 512B-1 are tied to a logic “0” level as shown.

FIG. 6B illustrates the manner in which the boundary-scan logic and bidirectional buffer circuitry is configured for operation in a system mode as an ordinary output buffer for device pin 522-2. The system mode function of device pin 522-2 is therefore output only. Note that the core logic 510 only connects to the buffer's output data and control terminals, via the signal lines denoted <port>O and <enb>, respectively, but the pin still has three boundary-scan cells and operates as a bidirectional pin in boundary-scan mode. The <enb> line may be set to a logic “1” level in the case of a two-state output, as indicated in the figure.

Certain of the connections shown between the input/output bidrectional buffers, boundary-scan cells and core logic in FIGS. 6A and 6B are similar to those commonly utilized in conventional boundary-scan arrangements, and will therefore not be further described herein. These include the connections associated with signal lines EN, ENSC, A, ASC, Z, ZSC, PU50 and PD50 of the bidirectional buffers.

The arrangements of FIGS. 6A and 6B illustrate that, in accordance with an aspect of the present invention, bidirectional buffers may be provided on all device pins that are to be grouped for sharing a common tester channel, regardless of the particular system mode functions of the device pins. That is, a bidirectional buffer is used for a given device pin in the illustrative embodiment even if the system mode function of that pin is input only or output only.

The boundary-scan logic and bidirectional buffer circuitry associated with other device pins of the FIG. 5 integrated circuit 502 may be configured in a manner the same as or similar to that illustrated for device pins 522-1 and 522-2 in FIGS. 6A and 6B, respectively.

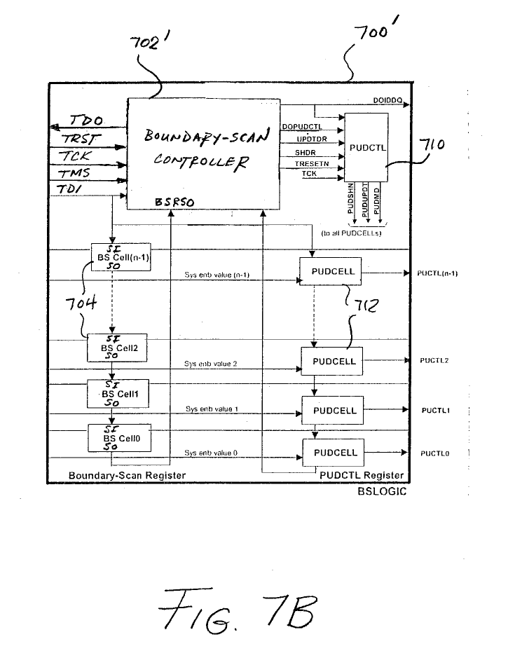

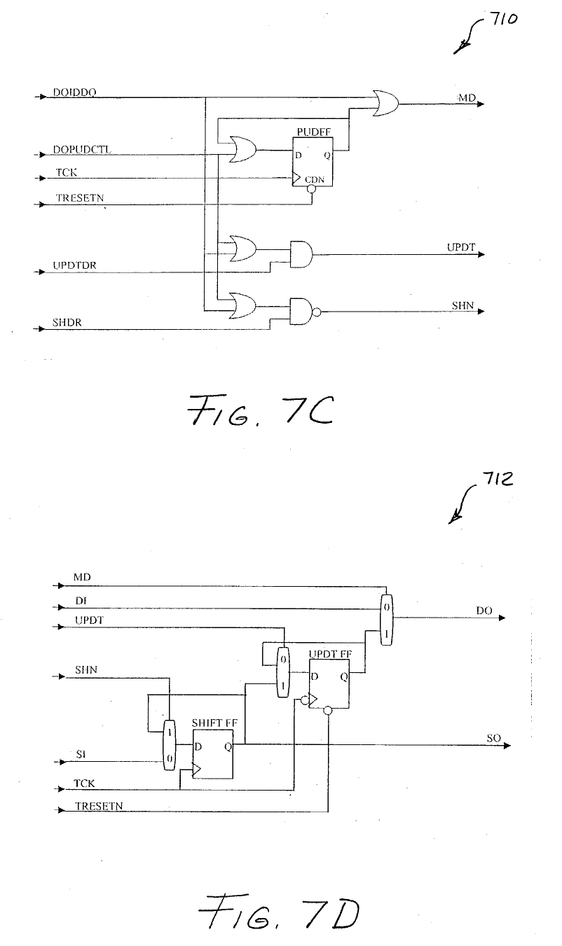

FIGS. 7A through 7D are schematic diagrams of illustrative boundary-scan logic circuitry. FIG. 7A shows a typical conventional arrangement, and FIGS. 7B through 7D illustrate arrangements utilizable in an integrated circuit or other device configured in accordance with the invention.

With reference initially to FIG. 7A, boundary-scan logic 700 in a typical conventional arrangement includes boundary-scan controller 702 and a boundary-scan register comprising n boundary-scan cells 704.

In this conventional arrangement, the boundary-scan cells 704 include logic that allows the boundary-scan mechanism to seize control of the device pins to apply and/or sense logic values. The boundary-scan controller 702 controls the application (e.g., capture, shifting and updating) of test patterns from the ATE to the boundary-scan cells 704 during device test. The operation of the boundary-scan controller 702 (which communicates with the ATE via the five boundary-scan control pins, TCK, TRST, TMS, TDI and TDO, as previously described herein) is defined by the IEEE 1149.1 standard and is well-known to those skilled in the art.

The boundary-scan cells 704 provide boundary-scan controllability and observability of the I/O buffers. These cells connect between the core logic and the I/O buffers as indicated in the figure. The SI and SO ports of the boundary-scan cells 704 are the serial input and serial output ports, respectively, for chaining the boundary-scan cells together. More particularly, the boundary-scan cells are daisy-chained, using their SI inputs and SO outputs, to form a boundary-scan register. The boundary-scan register is typically accessed via the TDI input and the TDO output through the boundary-scan controller 702. The boundary-scan register serial output data enters the BSRSO input of the boundary-scan controller 702. The boundary-scan controller 702 controls functions such as the capture, shifting and updating of the boundary-scan cells using control signals of a conventional type that are omitted from the figure for clarity of illustration.

FIG. 7B illustrates how the boundary-scan logic 700 of FIG. 7A may be modified to provide enhanced boundary-scan logic 700′ in accordance with an embodiment of the invention. The enhanced boundary-scan logic 700′ includes boundary-scan controller 702′, a pullup/pulldown control element 710, and a plurality of pullup/pulldown cells 712. As previously noted herein, there may be one or more of the pullup/pulldown cells associated with each of the device pins in a given integrated circuit to be tested.

The value of n in this embodiment may illustratively be 3N. That is, the n boundary-scan cells in FIG. 7B may be arranged, in accordance with the techniques of the invention, in sets of three cells each, with each set being associated with a corresponding one of N device pins. The boundary-scan cells 704′ may comprise control cells, output cells and input cells, for example, corresponding generally to cells 512A-i, 512B-i and 512C-i, respectively, in FIGS. 5 and 6.

The pullup/pulldown cells 712 allow the boundary-scan mechanism to seize control of the pullup and pulldown enables of the device I/O buffers. One possible implementation of a given one of the pullup/pulldown cells 712 is shown in FIG. 7D.

The enhanced boundary-scan controller 702′ controls the pullup/pulldown cells 712 via the pullup/pulldown control element 710. The boundary-scan controller 702′ is generally similar to the conventional boundary-scan controller 702 in FIG. 7A, except that it provides additional control signals to reset, shift and update logic patterns for accessing the pullup/pulldown register comprising the pullup/pulldown cells 712. The conventional boundary-scan controller 702 can be modified in a straightforward manner to provide these additional control signals.

As indicated in the figure, the additional control signals for accessing the pullup/pulldown register in an illustrative embodiment include signals denoted DOPUDCTL, TRESETN, SHDR and UPDTDR. The signal DOPUDCTL indicates that a pullup/pulldown access instruction is active. The signal TRESETN indicates when the boundary-scan state machine is in Test-Logic-Reset state and is used to reset the pullup/pulldown cell logic. The signals SHDR and UPDTDR are used to enable the respective shifting and data updating of the pullup/pulldown cells. These control signals do not directly connect to the pullup/pulldown cells 712, but instead communicate with the pullup/pulldown control element 710, the operation of which will be described in greater detail below.

It should be noted that the enhanced boundary-scan controller 702′ also generates a signal DOIDDQ, relating to an IDDQ test mode, that is supplied to the pullup/pulldown control element 710. Because the enhanced boundary-scan techniques of the invention can provide complete control of device I/O buffer pullup and pulldown enables, this capability can also be used to activate IDDQ test mode. An IDDQ test is a common test technique that places the device in a low-current mode and detects failures by sensing unexpectedly high current on the device power pins. IDDQ test mode generally requires disabling all device pin pullups and pulldowns, typically at the expense of a dedicated input pin. Because the enhanced boundary-scan techniques of the present invention can provide boundary-scan control of device pin pullups and pulldowns, a separate boundary-scan instruction can be defined for IDDQ test and the need for the dedicated IDDQ control pin is eliminated.

FIGS. 7C and 7D show more detailed schematic diagrams of exemplary implementations of the pullup/pulldown control element 710 and a given one of the pullup/pulldown cells 712, respectively.

More specifically, FIG. 7C shows an example implementation of the control logic PUDCTL shown in FIG. 7B. The signal PUDMD denotes a pullup/pulldown mode control signal, and in this implementation has a “sticky” nature, to be described below. When PUDMD is asserted, the pullup/pulldown cells seize control of the buffer pullup/pulldown control from the system core logic. This control logic 710 includes a pullup/pulldown flip-flop PUDFF and other logic gates arranged as shown. It is designed in such a way so that once PUDMD is asserted, it remains asserted even after other boundary-scan instructions necessary for ganging tests such as EXTEST are applied. Once set, PUDMD can only be released by resetting the boundary-scan controller, which asserts the reset signal TRESETN.

FIG. 7D represents an example implementation of a given one of the pullup/pulldown cells 712 of FIG. 7B. The given cell receives signals denoted MD, UPDT and SHN from the pullup/pulldown control element 710. The SI and SO notation indicates serial input and serial output ports, respectively, for chaining the pullup/pulldown cells together to form a pullup/pulldown control register.

During normal system operation, the buffer's pullup/pulldown control (DO) is controlled by the system core logic signal (DI). The MD signal controls whether DO is controlled by the system input DI or this pullup/pulldown cell. As in a conventional boundary-scan cell, the pullup/pulldown cell 712 includes a shift flip-flop for scanning in test patterns and an update flip-flop for applying the scanned-in patterns to the buffer's pullup/pulldown control. The update flip-flop typically must be initialized to the disabled state upon device initialization, e.g., when the boundary-scan controller is in a Test-Logic-Reset state.

The particular circuitry shown in FIGS. 7B through 7D can be used in whole or in part in any of the test systems described herein. It should be emphasized that the particular implementations shown are merely examples. Other types of circuitry can also be used. Moreover, the circuitry can be implemented at least in part using software.

FIG. 8 shows a test system 800 configured in accordance with another illustrative embodiment of the invention. The system 800 includes a device under test 802 which may comprise an integrated circuit, and ATE 804. The device under test 802 comprises core logic 810, boundary-scan cells denoted BSC, BSO and BSI, and a boundary-scan controller 814. As in the FIG. 1 system, the device under test 802 includes N device pins. These pins are coupled to the ATE 804 via a tester load board 830, which may alternatively be incorporated within the ATE. The boundary-scan controller 814 generates a boundary-scan mode signal BS_MD which is supplied to each of the boundary-scan cells BSC, BSO and BSI as shown.

The boundary-scan cells BSC, BSO and BSI are arranged in sets of three cells, each set including BSC, BSO and BSI elements and being associated with a corresponding bidirectional buffer and device pin.

The system 800 is shown in FIG. 8 as being configured to address an issue relating to ganging contention scenarios. Ganging contention in the context of the present invention can occur, by way of example, in the following situations:

1. During boundary-scan instructions where the pins are controlled by the system core logic (e.g., BYPASS, SAMPLE, IDCODE).

In this situation, the system-mode function controls the I/O buffer enables. Left to randomness, this could enable multiple drivers on a given multiple-pin group, resulting in potentially-damaging contention. To safeguard against this, a dedicated test input may be used to disable all of the system-mode buffer enable signals from the system core logic. This dedicated test input is shown as the GANGMODE signal in FIG. 8, and is supplied to the core logic 810 where, when asserted, it forces the Sysctl_A, Sysctl_B, . . . Sysctl_N signals to a state that disables their respective I/O buffers (e.g., places them in an input mode). This test input, which would typically only be activated during a test involving groups of device pins sharing a common tester channel, may be defined as a “Compliance Enable” pin in an IEEE 1149.1 BSDL file to ensure that it is tied disabled in system use.

2. During boundary-scan instructions where the pins are controlled by the boundary-scan logic (e.g., EXTEST, CLAMP, RUNBIST).

In this situation, the ganging test patterns loaded into the boundary-scan cells should be configured so as to prevent more than one buffer of the same group from being enabled at the same time. This may be done by ensuring that no more than one boundary-scan control cell that controls pins in a particular gang group is loaded with anything other than its “disable” value. There are also scenarios during these instructions where the system core logic function can influence the I/O buffer enables. The dedicated test input described above, however, provides protection from such scenarios.

Other arrangements of circuitry can be used to achieve ganging contention avoidance in accordance with the invention. This feature can be incorporated in a straightforward manner in the other example test systems described herein.

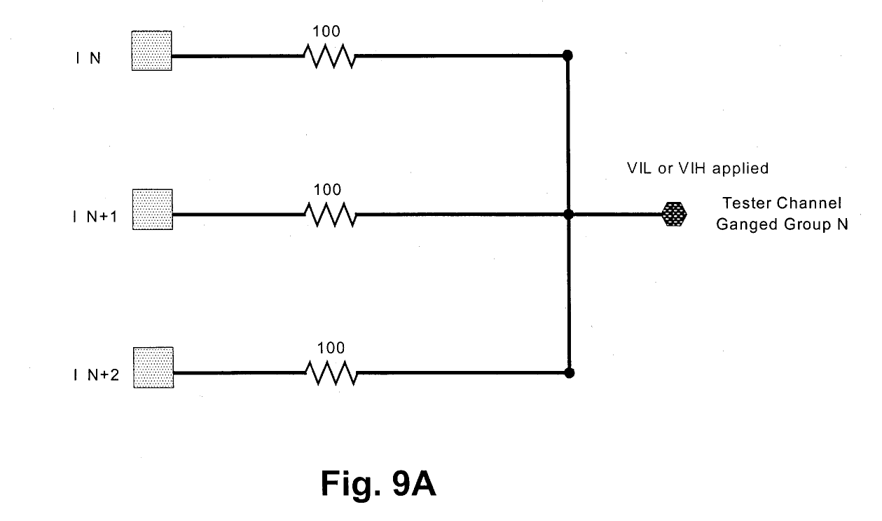

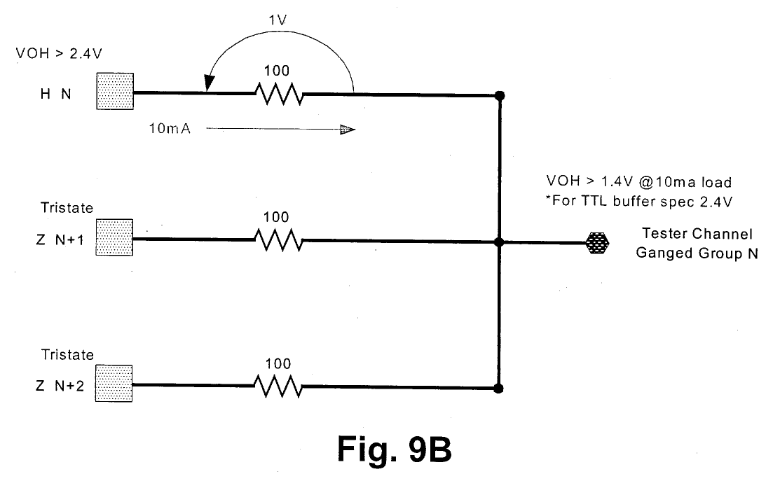

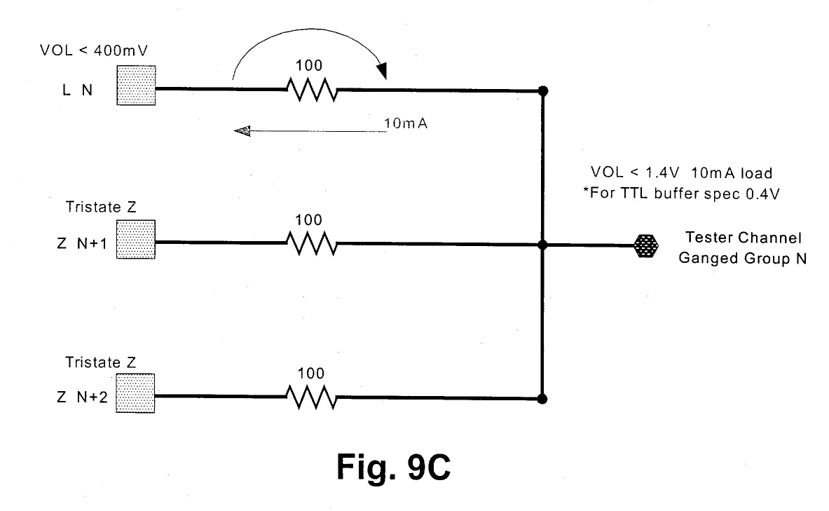

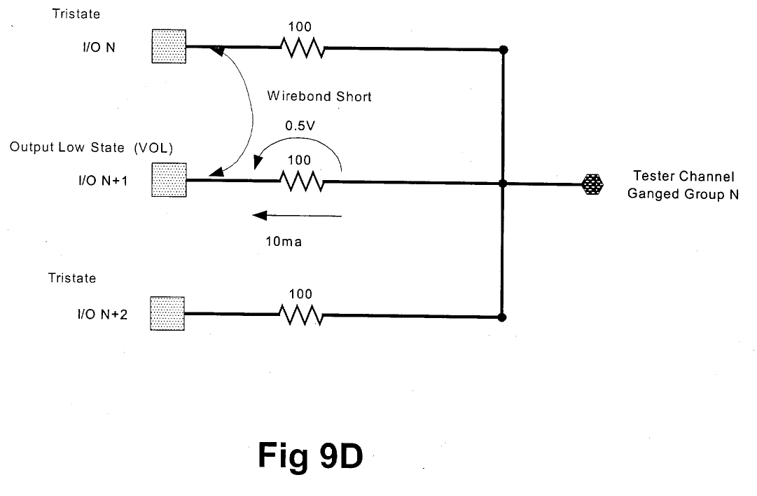

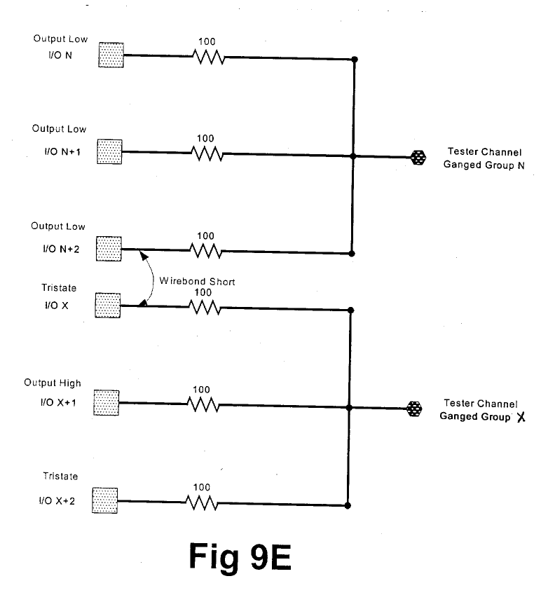

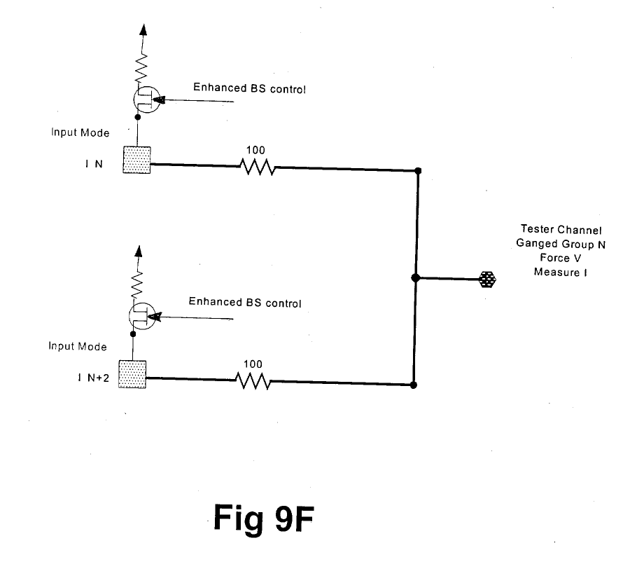

A number of example tests that can be performed in a test system in accordance with the invention will now be described in greater detail with reference to FIGS. 9A through 9F. It should be noted that the notation “N” in the context of FIGS. 9A through 9F is utilized differently than in other portions of the description. More particularly, in each of FIGS. 9A through 9F, “N” is utilized to indicate a particular ganged group of device pins associated with a single tester channel, as well as in denoting the specific device pins of the group. For example, with reference to FIG. 9A, a particular tester channel has a ganged group N of device pins associated therewith. The individual device pins in this context are denoted N, N+1 and N+2 as indicated in the figure. Although a given group includes only three device pins in these examples, other numbers of device pins per group may be used. Each of the device pins is coupled via a series resistor, assumed for illustrative purposes only to be 100 ohms, to the shared tester channel. The series resistors may be part of a tester load board, such as tester load board 130 of FIG. 2, or otherwise associated with the test equipment used to perform the test(s). The notation “I” utilized in conjunction with a given device pin in FIGS. 9A through 9F denotes an input mode, while the notation “Z” denotes a tristate mode. Other notations utilized in these figures include “L”, “H”, and “I/O” denoting low, high and input/output, respectively.

Ganged Input Level Testing

For ganged input level testing, the input levels may be applied in parallel to each pin in a given multiple-pin group and the results monitored by boundary-scan techniques. Since there is negligible current flow through the series resistors of the tester load board for this test, the input levels applied from tester pin electronics associated with the tester channel to the actual device pins in the group will be substantially the same.

The ganged input level testing is typically performed for both VIL and VIH levels. For VIL testing, the ATE applies a minimum threshold level, which all input boundary-scan cells of the group capture. The boundary-scan cell contents are scanned out to make sure that the buffers detected this minimum threshold level. For VIH testing, the process is repeated with the ATE applying a maximum threshold level.

FIG. 9A shows an example of this test for a ganged group N of device pins N, N+1 and N+2. In this example, each device pin is in an input mode, and a VIL level or VIH level is applied to the tester channel.

Leakage Testing

Leakage testing is also performed in parallel for the device pins of a given group. As noted above, it is generally preferable that the bidirectional buffers associated with a given grouping of multiple pins sharing a common tester channel of the ATE have substantially the same DC characteristics. The use of ganged leakage measurements may constrain the maximum number of pins that can be contained in a given group. In a ganged group, the sum of all pin leakages is measured and compared against a single threshold set by the ATE, to determine if the aggregate leakage current exceeds expectations. The arrangement illustrated in FIG. 9A may be utilized for this test.

VOH Testing

For output high voltage level (VOH) testing, a single buffer associated with a particular device pin in the given group is placed in an output high mode while the buffers associated with the other pins of the group are placed in a tristate mode or an input mode, and the particular pin is tested. This process is repeated for each of the pins in the group, that is, the corresponding buffers are sequentially enabled such that while a particular pin is tested all other pins in the group have their buffers set to a tristate mode or an input mode. The voltage drop across the series resistor of the tester load board should be taken into account in determining the actual VOH level at the device pin.

FIG. 9B shows an example of this test for the ganged group N. In order to meet a VOH>2.4 volt TTL buffer specification at the device pin N, a measurement of VOH>1.4 V is required at the tester channel, taking into account a drop of 1 volt across the 100 ohm series resistor at 10 milliamps.

VOL Testing

The testing of output low voltage level (VOL) proceeds in a similar manner to the VOH testing described above. More specifically, a single buffer associated with a particular device pin in the given group is placed in an output low mode while the buffers associated with the other pins of the group are placed in a tristate mode or an input mode, and the particular pin is tested. This process is repeated for each of the pins in the group, that is, the corresponding buffers are sequentially enabled such that while a particular pin is tested all other pins in the group have their buffers set to a tristate mode or an input mode. Again, the voltage drop across the series resistor of the tester load board should be taken into account in determining the actual VOL level at the device pin.

FIG. 9C shows an example ofthis test for the ganged group N. In order to meet a VOL<400 millivolt TTL buffer specification at the device pin N, a measurement of VOL<1.4 V is required at the tester channel, taking into account a drop of 1 volt across the 100 ohm series resistor at 10 milliamps.

Short Detection within a Group

To test for a short between device pins of a given group, e.g., a wirebond short between device pins, the buffer associated with a particular one of the pins is placed in an output low mode while the buffers associated with all other pins of the group are placed in a tristrate mode. A short between the given pin and one of the other pins of the group will reduce the associated series resistance by a factor of one-half, and can be detected by monitoring the output low voltage. As in the VOH and VOL tests, the process is repeated for each of the device pins.

FIG. 9D shows an example of this test for the ganged group N, illustrating the manner in which a wirebond short between two pins of the group can be detected.

Short Detection Between Groups

In a typical implementation, the above-described “Short Detection Within A Group” test is performed within each multiple-pin group, and is then followed by a test for shorts from each group to the other groups and any non-ganged pins, and from each non-ganged pin to the other non-ganged pins. In other words, a short detection test can be performed that simply treats each multiple-pin group as a single pin.

During the “Short Detection Between Groups” test, only one pin in a multiple-pin group is placed in output mode, while all others are in input mode. Treating each multiple-pin group as an individual pin, a short detection test is then performed. The short detection test may involve well-known conventional techniques such as, for example, applying “walking” bit patterns using a modified Wagner algorithm to the pins and verifying that each pin senses only what it drives. Short detection tests suitable for use in conjunction with the invention are well understood by those skilled in the art and will therefore not be further described herein.

FIG. 9E shows an example of the “Short Detection Between Groups” test for the ganged groups N and X, illustrating the manner in which a wirebond short between a pin of group N and a pin of group X can be detected.

Pullup/Pulldown Testing

As indicated above, the pullup/pulldown cells associated with the device pins of a given group can be individually controlled. Therefore, to test the pullup resistor or pulldown resistor of a particular device pin in the group, the corresponding resistor is enabled while the buffers associated with one or more other pins may be placed in a tristate mode.

FIG. 9F shows an example of this test for two pins of the ganged group N. Pullup resistors associated with each pin are controlled using the enhanced boundary-scan control circuitry previously described herein. The shared tester channel forces a given voltage and measures the resulting current.

It should be appreciated that the particular tests described above are provided by way of illustrative example only. The invention does not require the use of these particular test techniques, and numerous alternative techniques suitable for use in a test system of the present invention will be apparent to those skilled in the art.

The associating of a group of multiple device pins with a single tester channel in accordance with the invention provides a number of significant advantages relative to conventional techniques. For example, the reduction in tester channel requirements provided by the present invention allows high pin count devices to be tested using existing low-cost test equipment, thereby eliminating the need for expensive new equipment. Capital expenditures may thus be deferred while maintaining desired levels of test flexibility using common existing tester platforms.

It should be noted that the present invention may be implemented at least in part in the form of software running on the ATE or other suitable test equipment device or platform. Such software may comprise instructions or other commands deliverable to an integrated circuit or other device under test to implement the test operations described herein.

The above-described embodiments of the invention are intended to be illustrative only. Numerous other alternative embodiments may be devised by those skilled in the art without departing from the scope of the following claims. For example, numerous alternative configurations of test circuitry elements such as boundary-scan registers, pullup/pulldown registers, bidirectional buffers, and tester load boards can be used. Also, the techniques of the invention may be used to test a wide variety of types and arrangements of electronic circuitry other than those specifically shown and described herein. These and other alternative embodiments will be readily apparent to those skilled in the art.

What is claimed is:

1. An apparatus comprising:
electronic circuitry connectable to test equipment having a plurality of tester channels;
a plurality of device pins of the electronic circuitry being designatable as comprising a group, a designated multiple-pin group being assignable to one of the tester channels;
wherein a test is performable on the electronic circuitry, via the assigned tester channel, utilizing at least a subset of the device pins in the designated multiple-pin group.

2. The apparatus of claim 1 wherein the electronic circuitry comprises an integrated circuit.

3. The apparatus of claim 1 wherein the electronic circuitry further comprises:
boundary-scan logic circuitry; and
a plurality of bidirectional buffers;
wherein each of the bidirectional buffers is coupled to a corresponding one of the device pins.

4. The apparatus of claim 3 wherein the boundary-scan logic circuitry comprises a boundary-scan register and a pullup/pulldown control register.

5. The apparatus of claim 4 wherein the boundary-scan register comprises a plurality of sets of boundary-scan cells, wherein each of the sets of boundary-scan cells includes one or more boundary-scan cells and is associated with a corresponding one of the device pins.

6. The apparatus of claim 5 wherein a given one of the sets of boundary-scan cells comprises at least a boundary-scan control cell, a boundary-scan output cell, and a boundary-scan input cell.

7. The apparatus of claim 5 wherein a given one of the sets of boundary-scan cells comprises at least a boundary-scan control cell and a bidirectional boundary-scan cell.

8. The apparatus of claim 4 wherein the pullup/pulldown control register comprises a plurality of sets of pullup/pulldown cells, wherein each of the sets of pullup/pulldown cells includes one or more pullup/pulldown cells and is associated with a corresponding one of the device pins.

9. The apparatus of claim 3 wherein the boundary-scan logic circuitry comprises circuitry associated with provision of a contention avoidance mode among the device pins in the multiple-pin group.

10. A method of testing electronic circuitry utilizing test equipment comprising a plurality of tester channels, the method comprising the steps of:
designating a group comprising a plurality of device pins of the electronic circuitry;
assigning the designated multiple-pin group to one of the tester channels; and
performing a test on the electronic circuitry, via the assigned tester channel, utilizing at least a subset of the device pins in the designated multiple-pin group.

11. The method of claim 10 wherein the test is performed on the electronic circuitry utilizing at least one standard boundary-scan command and at least one non-standard boundary-scan command.

12. The method of claim 11 wherein the standard command comprises a command specified by the IEEE 1149.1 standard.

13. The method of claim 11 wherein the non-standard command comprises a pullup/pulldown control command.

14. The method of claim 10 wherein the test performed on the electronic circuitry, via the assigned tester channel, utilizing at least a subset of the device pins in the designated multiple-pin group, comprises at least one of an input level test, a leakage test, an output level test, an intra-group short detection test, an inter-group short detection test, a pullup/pulldown test, and an IDDQ test.

15. An apparatus for use in testing electronic circuitry, the apparatus comprising:
test equipment having a plurality of tester channels, the test equipment being operative to perform a test on the electronic circuitry;
wherein a group comprising a plurality of device pins of the electronic circuitry is designated, and the designated multiple-pin group is assigned to one of the tester channels; and
wherein the test is performed on the electronic circuitry, via the assigned tester channel, utilizing at least a subset of the device pins in the designated multiple-pin group.

16. The apparatus of claim 15 wherein the test equipment comprises automated test equipment (ATE).

17. The apparatus of claim 15 wherein the test equipment has associated therewith a tester load board, the tester load board comprising a plurality of resistors, each of the resistors connectable between a corresponding one of the device pins of the multiple-pin group and the assigned tester channel.

18. The apparatus of claim 17 wherein the tester load board is incorporated within the test equipment.

19. A test system comprising:
test equipment having a plurality of tester channels;
electronic circuitry connectable to the test equipment, the test equipment being operative to perform a test on the electronic circuitry;
wherein a group comprising a plurality of device pins of the electronic circuitry is designated, and the designated multiple-pin group is assigned to one of the tester channels; and
wherein the test is performed on the electronic circuitry, via the assigned tester channel, utilizing at least a subset of the device pins in the designated multiple-pin group.

20. An article of manufacture comprising a machine-readable storage medium storing one or more software programs for testing electronic circuitry utilizing test equipment comprising a plurality of tester channels, wherein the one or more software programs when executed implement the steps of:
designating a group comprising a plurality of device pins of the electronic circuitry;
assigning the designated multiple-pin group to one of the tester channels; and
performing a test on the electronic circuitry, via the assigned tester channel, utilizing at least a subset of the device pins in the designated multiple-pin group.

21. An integrated circuit comprising:
core logic circuitry;
a plurality of device pins;
input/output circuitry coupled between the plurality of device pins and the core logic circuitry; and
boundary-scan logic circuitry coupled to the core logic circuitry and the input/output circuitry, the boundary scan logic circuitry comprising a boundary-scan register and a pullup/pulldown control register;
the boundary-scan register comprising a plurality of sets of boundary-scan cells, wherein each of the sets of boundary-scan cells includes one or more boundary-scan cells and is associated with a corresponding one of the device pins;
the pullup/pulldown register comprising a plurality of sets of pullup/pulldown cells, wherein each of the sets of pullup/pulldown cells includes one or more pullup/pulldown cells and is associated with a corresponding one of the device pins.
